(19) United States
(12) Patent Application Publication
(10) Pub. No.: US 2024/0098926 A1
(43) Pub. Date: Mar. 21, 2024

(54) SWITCHING MODULE, POWER CONVERSION DEVICE, AND MANUFACTURING METHOD FOR POWER CONVERSION DEVICE

(71) Applicant: KABUSHIKI KAISHA YASKAWA DENKI, Fukuoka (JP)

(72) Inventors: Kenshiro MORISHITA, Fukuoka (JP); Mitsutaka ONO, Fukuoka (JP); Yasunori YAMANAKA, Fukuoka (JP)

(21) Appl. No.: 18/468,377

(22) Filed: Sep. 15, 2023

(30) Foreign Application Priority Data
Sep. 21, 2022 (JP) 2022-150476

(51) Int. Cl. H05K 7/14; H02M 1/32; H05K 7/20

(52) U.S. Cl. CPC H05K 7/14322; H02M 1/327; H05K 7/14324; H05K 7/14339; H05K 7/209; H05K 3/341

(57) ABSTRACT

Object: To reduce the size of a device. Solution to Problem: A switching module according to one aspect of the present disclosure is a module used in a power conversion circuit. The switching module includes a case member formed to extend in a first direction and a second direction, one or more switching elements disposed to face the case member in a stacking direction orthogonal to the first direction and the second direction, and a pressing member configured to press at least part of the one or more switching elements toward one side in the stacking direction via the case member. The one or more switching elements are disposed closer one end portion of both end portions of the case member in the second direction.

### CROSS-REFERENCE TO RELATED APPLICATIONS

This application claims priority pursuant to 35 U.S.C. 119(a) to Japanese Application No. 2022-150476, filed Sep. 21, 2022, which application is incorporated herein by reference in its entirety.

### TECHNICAL FIELD

The present disclosure relates to a switching module, a power conversion device, and a manufacturing method for the power conversion device.

### BACKGROUND ART

Patent Document 1 discloses a power conversion device including a heat sink, a case that accommodates an electronic component, and a pressing member that presses the electronic component toward the heat sink.

### CITATION LIST

### Patent Literature

Patent Document 1: JP 2017-98329 A

### SUMMARY OF INVENTION

### Technical Problem

The present disclosure provides a switching module, a power conversion device, and a manufacturing method for the power conversion device effective for reducing the size of a device.

### Solution to Problem

A switching module according to one aspect of the present disclosure is a module used in a power conversion circuit. The switching module includes a case member formed to extend in a first direction and a second direction, one or more switching elements disposed to face the case member in a stacking direction orthogonal to the first direction and the second direction, and a pressing member configured to press at least part of the one or more switching elements toward one side in the stacking direction via the case member. The one or more switching elements are disposed closer to one end portion of both end portions of the case member in the second direction.

A manufacturing method for a power conversion device according to one aspect of the present disclosure includes a first assembly step of assembling a switching module, an attachment step of attaching the switching module to a circuit board, a board step of performing soldering on the circuit board after the attachment step, and a second assembly step of fixing the switching module attached to the circuit board to a heat sink after the board step. The first assembly step includes preparing one or more switching elements, a case member formed to extend in a first direction and a second direction orthogonal to each other, and a pressing member configured to press at least part of the one or more switching elements, disposing the one or more switching elements to face the case member in a stacking direction orthogonal to the first direction and the second direction and to be positioned closer to one end portion of both end portions of the case member in the second direction, and disposing the pressing member to overlap at least part of the one or more switching elements via the case member in the stacking direction. The second assembly step includes fixing a switching module together with a circuit board to a heat sink so that at least part of the one or more switching elements is pressed toward the heat sink by the pressing member.

### Advantageous Effects of Invention

With the present disclosure, a switching module, a power conversion device, and a manufacturing method for the power conversion device effective for reducing the size of a device are provided.

### BRIEF DESCRIPTION OF DRAWINGS

FIG. 1 is a schematic view of an example of a power generation system including a power conversion device.

FIG. 2 is a diagram illustrating an example of a switch circuit.

FIG. 3 is an exploded perspective view schematically illustrating an example of a configuration of the power conversion device.

FIG. 4 is a top view schematically illustrating an example of a layout on a circuit board.

FIG. 5 is an exploded perspective view schematically illustrating an example of a switching module.

FIG. 6(a) is a bottom view schematically illustrating an example of a case member.

FIG. 6(b) is a schematic view illustrating an example of a state in which the switching element is accommodated in the case member.

FIG. 7(a) is a top view schematically illustrating an example of a cover member. FIGS. 7(b) and 7(c) are cross-sectional views schematically illustrating an example of a fixing portion provided in the cover member.

FIG. 8(a) is a perspective view schematically illustrating an example of a switching module. FIG. 8(b) is a cross-sectional view schematically illustrating an example of the switching module.

FIG. 9 is a top view schematically illustrating an example of a layout on a circuit board.

FIGS. 10(a) and 10(b) are flowcharts illustrating an example of a manufacturing process for the power conversion device.

FIGS. 11(a) to 11(c) are schematic views illustrating an example of a state of the manufacturing process for the power conversion device.

### DESCRIPTION OF EMBODIMENTS

An embodiment will be described below with reference to the drawings. In the description, elements which are the same or have the same function are given the same reference signs, and redundant descriptions thereof are omitted. In some drawings, an orthogonal coordinate system defined by an X axis, a Y axis, and a Z axis is illustrated.

### Circuit Configuration of Power Conversion Device

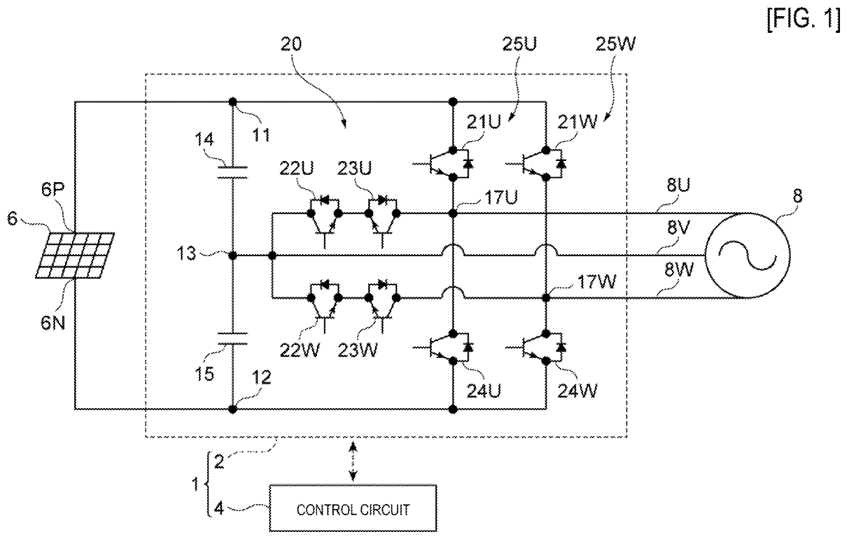

A power conversion device 1 illustrated in FIG. 1 is a device that converts a direct current (DC current) into an alternating current (AC current). The power conversion device 1 is used in, for example, a photovoltaic power generation system. The photovoltaic power generation system including the power conversion device 1 is a system that converts a direct current generated in response to incidence of sunlight in a power generation device 6 into an alternating current corresponding to a power grid 8 and outputs the alternating current to the power grid 8. The power grid 8 is a system that supplies AC power to consumers such as general households and factories. The power grid 8 may be a commercial power grid operated by a power company or the like. The alternating current corresponding to the power grid 8 is, for example, a three-phase alternating current including a U-phase 8U, a V-phase 8V, and a W-phase 8W. The V-phase 8V may be grounded.

The power generation device 6 is an example of a direct-current power supply, generates a direct current in response to incidence of sunlight, and outputs the generated direct current to a positive electrode 6P and a negative electrode 6N. The power conversion device 1 converts the direct current generated by the power generation device 6 into an alternating current corresponding to the power grid 8. The power conversion device 1 may boost the direct current generated by the power generation device 6 and then convert the resultant current into an alternating current corresponding to the power grid 8. The power conversion device 1 includes a power conversion circuit 2 and a control circuit 4 as a circuit configuration.

The power conversion circuit 2 is a circuit that converts the direct current generated by the power generation device 6 into an alternating current and outputs the alternating current to the power grid 8. The power conversion circuit 2 may be a circuit that outputs a three-phase alternating current to the power grid 8. The power conversion circuit 2 may include a circuit that boosts the direct current. The power conversion circuit 2 includes, for example, a first point 11, a second point 12, a third point 13, a first capacitor 14, a second capacitor 15, and a switching circuit 20. The first point 11 is connected to the positive electrode 6P of the power generation device 6. The second point 12 is connected to the negative electrode 6N of the power generation device 6. The third point 13 is connected to the first point 11 via the first capacitor 14 and to the second point 12 via the second capacitor 15. While one first capacitor 14 is illustrated in FIG. 1, the first capacitor 14 may include a plurality of capacitors connected in parallel to each other. Similarly, the second capacitor 15 may include a plurality of capacitors connected in parallel to each other.

The switching circuit 20 is an inverter circuit. The switching circuit 20 converts the direct current generated by the power generation device 6 into an alternating current by changing a connection state between the power generation device 6 on the primary side and the power grid 8 on the secondary side, using a plurality of switching elements. Each of the plurality of switching elements included in the switching circuit 20 is, for example, an insulated gate bipolar transistor (IGBT). The switching element included in the switching circuit 20 may be a switching element other than the IGBT, such as a power metal oxide semiconductor field effect transistor (MOSFET). In each of the plurality of switching elements, switching between an ON state and an OFF state occurs in accordance with a gate drive signal.

In one example, the switching circuit 20 generates three-phase alternating current corresponding to the power grid 8 by maintaining a state in which the third point 13 is connected to any one phase (for example, the U-phase 8U) of the electric power grid 8, and connecting and disconnecting each of the first point 11 and the second point 12 to and from the remaining two phases (for example, the V-phase 8V and the W-phase 8W) of the electric power grid 8. The switching circuit 20 may be a three-level inverter circuit. FIG. 1 illustrates an example of a circuit configuration in which the switching circuit 20 is of a three-level bidirectional switch type. When the switching element is an IGBT, the current flowing between the switching element and the power grid 8 flows from the collector to the emitter of the switching element. The switching circuit 20 may include a plurality of switching elements corresponding to the U-phase 8U and a plurality of switching elements corresponding to the W-phase 8W.

The plurality of switching elements corresponding to the U-phase 8U include a switching element 21U, a switching element 22U, a switching element 23U, and a switching element 24U. The switching circuit 20 has a connection point 17U, and the connection point 17U is connected to the first point 11 via the switching element 21U. The connection point 17U is connected to the third point 13 via the switching element 22U and the switching element 23U. The switching element 22U and the switching element 23U are connected in series with their emitters connected to each other. Unlike the example illustrated in FIG. 1, the switching element 22U and the switching element 23U may have their collectors connected to each other, and when this pair of switching elements are of a reverse blocking type, the pair of switching elements may be connected in anti-parallel. The connection point 17U is connected to the second point 12 via the switching element 24U. The connection point 17U is also connected to the U-phase 8U of the power grid 8.

A switch group corresponding to the W-phase 8W includes a switching element 21W, a switching element 22W, a switching element 23W, and a switching element 24W. The switching circuit 20 has a connection point 17W, and the connection point 17W is connected to the first point 11 via the switching element 21W. The connection point 17W is connected to the third point 13 via the switching element 22W and the switching element 23W. The switching element 22W and the switching element 23W are connected in series with their emitters connected to each other. Unlike the example illustrated in FIG. 1, the switching element 22W and the switching element 23W may have their collectors connected to each other, and when this pair of switching elements are of a reverse blocking type, the pair of switching elements may be connected in anti-parallel. The connection point 17W is connected to the second point 12 via the switching element 24W. The connection point 17W is also connected to the W-phase 8W of the power grid 8.

The third point 13 is connected to the V-phase 8V of the power grid 8 with none of the switching elements of the switching circuit 20 provided in between. Note that other circuit elements such as switches and filters may be provided between the connection point 17U and the U-phase 8U, between the connection point 17W and the W-phase 8W, and between the third point 13 and the V-phase 8V.

The switch group including the switching element 21U, the switching element 22U, the switching element 23U, and the switching element 24U (hereinafter referred to as “switch group 25U”) can form one arm in the inverter circuit. The switch group including the switching element 21W, the switching element 22W, the switching element 23W, and the switching element 24W (hereinafter referred to as “switch group 25W”) can form one arm in the inverter circuit. The switching element 21U and the switching element 21W are disposed at mutually corresponding positions in the respective arms, and have the same function (role). Similarly, the switching elements 22U and 22W, the switching elements 23U and 23W, and the switching elements 24U and 24W are disposed at mutually corresponding positions in the respective arms and have the same function (role).

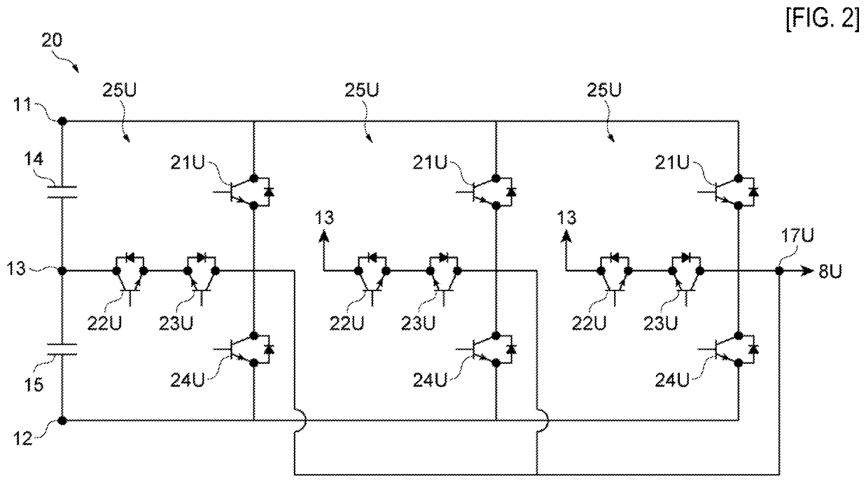

In FIG. 1, one switch group 25U is illustrated for the U-phase 8U. As illustrated in FIG. 2, the arm related to the U-phase 8U may include a plurality of (three in FIG. 2) the switch groups 25U. One switch group 25U is a minimum unit with which the arm related to the U-phase 8U can be formed (function) in the inverter circuit. The number of switch groups 25U is selected in accordance with, for example, the capacitance (for example, the maximum current value) in the main circuit of the power conversion circuit 2. Between the first point 11 and the second point 12, a plurality of sets of switching element 21U and switching element 24U included in the plurality of switch groups 25U may be connected in parallel to each other. Between the third point 13 and the connection point 17U, a plurality of sets of switching element 22U and switching element 23U included in the plurality of switch groups 25U may be connected in parallel to each other.

The plurality of switching elements 21U in the plurality of switch groups 25U are disposed at mutually corresponding positions in one arm and have the same function (role). As in the case of the plurality of switching elements 21U, the plurality of switching elements 22U, the plurality of switching elements 23U, and the plurality of switching elements 24U in the plurality of switch groups 25U are also disposed at mutually corresponding positions in one arm and have the same function (role). The arm of the inverter circuit related to the W-phase 8W may include one switch group 25W or the plurality of switch groups 25W, as in the arm related to the U-phase 8U. One switch group 25W is a minimum unit with which the arm related to the W-phase 8W in the inverter circuit can be formed (caused to function).

Referring back to FIG. 1, the control circuit 4 controls the power conversion circuit 2 to generate the alternating current corresponding to the power grid 8 and output the generated alternating current to the power grid 8. For example, the control circuit 4 controls the switching circuit 20 to generate the alternating current corresponding to the power grid 8 based on the maximum power that can be generated by the power generation device 6. When controlling the switching circuit 20, the control circuit 4 outputs a gate drive signal to each of the plurality of switching elements included in the switching circuit 20.

### Device Configuration of Power Conversion Device

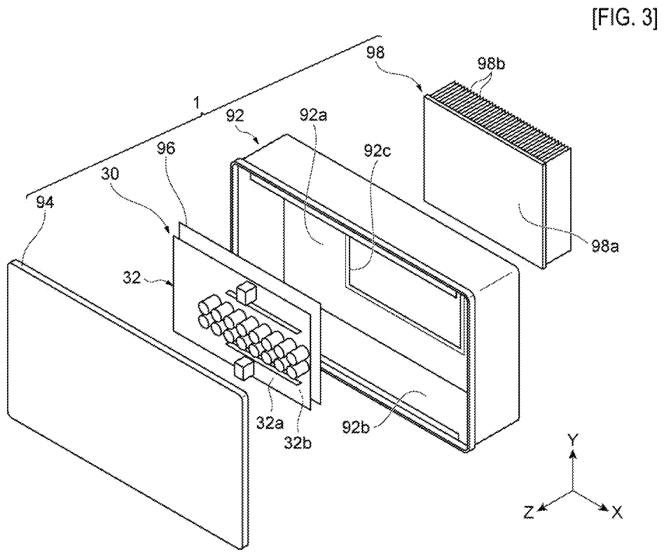

Next, a device configuration (various members forming the power conversion device 1) of the power conversion device 1 including the power conversion circuit 2 and the control circuit 4 described above will be described with reference to FIGS. 3 to 9. As illustrated in FIG. 3, the power conversion device 1 includes, for example, a circuit body 30, a housing 92, a cover 94, an insulating sheet 96, and a heat sink 98. In FIG. 3, the members included in the power conversion device 1 are illustrated in an exploded manner, and some members of the power conversion device 1 are omitted for the sake of description.

The circuit body 30, the insulating sheet 96, and the heat sink 98 are stacked in one direction. Hereinafter, the direction in which the circuit body 30, the insulating sheet 96, and the heat sink 98 are stacked (disposed) is referred to as a “Z-axis direction”. The circuit body 30, the insulating sheet 96, and the heat sink 98 are stacked side by side in this order in the Z-axis direction (stacking direction). In the present disclosure, each member of the power conversion device 1 will be described based on a state in which the power conversion device 1 is disposed such that the Z-axis direction substantially coincides with the up-down direction and the circuit body 30 is located on the upper side of the heat sink 98. Each member of the power conversion device 1 in a state in which the power conversion device 1 is assembled will be described. A direction from the heat sink 98 toward the circuit body 30 is defined as “up” or “upper side”, and a direction from the circuit body 30 toward the heat sink 98 is defined as “down” or “lower side”.

The circuit body 30 is a member that forms at least part of the main circuit of the power conversion circuit 2 and at least part of the control circuit 4 in the power conversion device 1. The circuit body 30 includes a circuit board 32. In the circuit body 30, various electronic components and a component module formed by integrating a plurality of electronic components are mounted on the circuit board 32. The circuit board 32 is, for example, a printed board formed in a rectangular shape. The circuit board 32 may be disposed in a state of being orthogonal to the Z-axis direction. The circuit board 32 has a pair of principal surfaces opposite to each other in the Z-axis direction. Hereinafter, one principal surface (component mounting surface) of the circuit board 32 of the circuit body 30 facing upward is referred to as a “front surface 32a”, and the other principal surface (component mounting surface) of the circuit board 32 facing downward is referred to as a “back surface 32b”. In addition, a direction in which one outer edge (for example, a long side) of the circuit board 32 extends is referred to as an “X-axis direction”, and a direction in which another outer edge (for example, a short side) orthogonal to the outer edge along the X-axis direction of the circuit board 32 extends is referred to as a “Y-axis direction”. Details of the circuit body 30 will be described later.

The housing 92 is a member that accommodates the circuit body 30. The housing 92 includes a bottom wall 92a and a peripheral wall 92b. The bottom wall 92a is formed in a rectangular shape and extends in the X-axis and Y-axis directions. The peripheral wall 92b extends upward from peripheral edge portions of the bottom wall 92a, and forms an accommodation space together with the bottom 92a. The cover 94 has a shape corresponding to the bottom wall 92a and is attached to an upper end portion of the peripheral wall 92b so as to close the accommodation space of the housing 92. An opening 92c having a shape corresponding to the circuit board 32 is formed in the bottom wall 92a of the housing 92.

The insulating sheet 96 is stacked on one side of the circuit body 30 in the Z-axis direction. The circuit body 30 and the insulating sheet 96 are attached to the bottom wall 92a in a state where the insulating sheet 96 is exposed to the outside of the accommodation space of the housing 92 from the opening 92c. The insulating sheet 96 has a function of maintaining insulation between the circuit body 30 and the heat sink 98.

The heat sink 98 radiates heat generated in the circuit body 30 to cool the circuit body 30. The circuit body 30 is fixed to the heat sink 98. The heat sink 98 includes, for example, a base portion 98a and a plurality of heat radiation fins 98b provided on the base portion 98a. The base portion 98a is formed in a rectangular shape so as to correspond to the opening 92c. The heat sink 98 is attached to the outer surface of the bottom wall 92a so that the base portion 98a faces the insulating sheet 96 in the opening 92c. With the circuit body 30 fixed to the heat sink 98 via the insulating sheet 96, heat generated in the circuit body 30 is transmitted to the heat sink 98, and thus heat is dissipated from the circuit body 30 (the circuit body 30 cooled).

### Switching Module

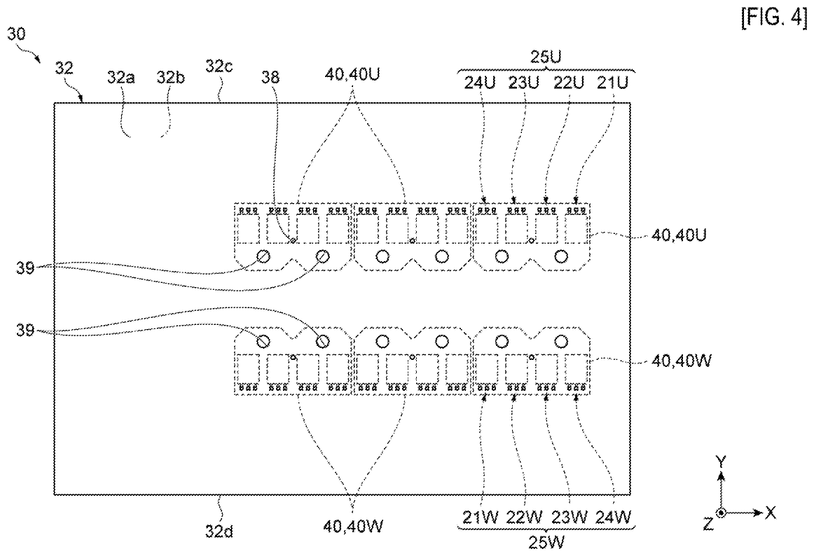

For example, the circuit body 30 includes a plurality of switching modules 40. As illustrated in FIG. 4, the plurality of switching modules 40 are provided so as to face the back surface 32b (second main surface) of the circuit board 32. FIG. 4 schematically illustrates the circuit body 30 as viewed from above, with various electronic components and the like provided on the front surface 32a of the circuit board 32 omitted. The plurality of switching modules 40 have the same shape. In the following, the structure of one switching module 40 will be described, and then the layout on the circuit board 32 will be described.

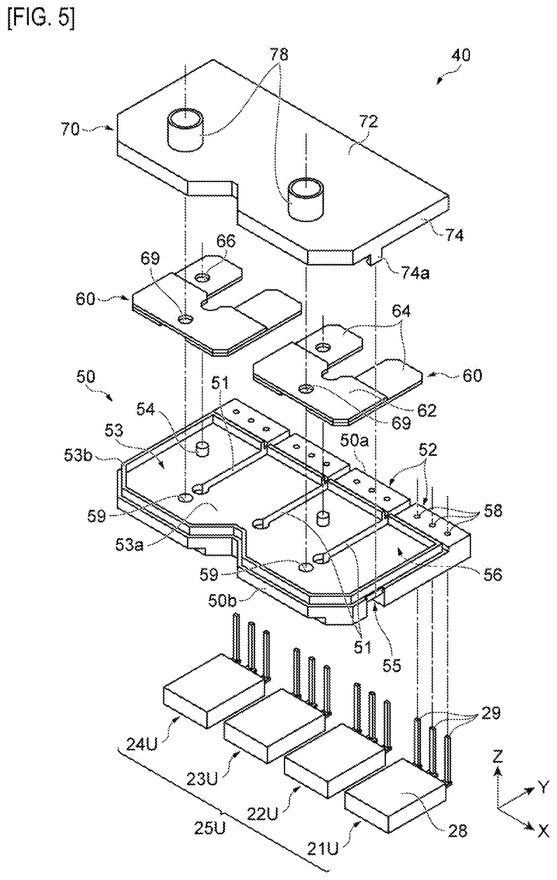

FIG. 5 illustrates one switching module 40 in an exploded manner, for the sake of description. The switching module 40 is a module used in the power conversion circuit 2. The switching module 40 is formed by packaging one or more switching elements included in the switching circuit 20 of the power conversion circuit 2 and members other than the switching elements. The switching element (each switching element) included in the switching module 40 is a discrete component (element unit) manufactured individually. In the following, a case is described where four switching elements are packaged as one module together with other members will be described by taking the switching module 40 used for the arm of the U-phase 8U as an example.

The switching module 40 includes, for example, a case member 50, the switching elements 21U, 22U, 23U, and 24U, pressing members 60 and 60 (two pressing members), and a cover member 70. In the Z-axis direction, the switch group including the switching elements 21U, 22U, 23U, and 24U, the case member 50, the pressing member 60, and the cover member 70 are disposed in this order from the lower side. The switching elements 21U, 22U, 23U, and 24U may be disposed at the same position in the Z-axis direction. In the switching module 40, the positional relationship between the switching element and the other members means the positional relationship between a main body portion (the portion excluding lead terminals) of the switching elements and the other members unless otherwise specified. The case member 50 and the pressing member 60 may have an integral structure.

The case member 50 is a member that maintains insulation between the switching elements and the pressing member 60 and regulates the positions of the switching elements 21U, 22U, 23U, and 24U and the pressing member 60. The case member 50 is formed of an insulating material (for example, resin). The case member 50 is formed in a plate shape on the whole, and has a rectangular shape in plan view (viewed from above). The case member 50 is formed so as to extend in the X-axis direction (first direction) and the Y-axis direction (second direction). The length of the case member 50 in the X-axis direction may be longer than the length of the case member 50 in the Y-axis direction.

Here, one end portion among both end portions of the case member 50 in the Y-axis direction is referred to as an “end portion 50a”, and the other end portion is referred to as an “end portion 50b”. The case member 50 has a plurality of (three) slits 51 formed to extend along the Y-axis direction from the end portion 50a to a position between the center in the Y-axis direction and the end portion 50b. Each of the three slits 51 is formed through the case member 50 (the main body portion of the case member 50) in the Z-axis direction. The three slits 51 are disposed at equal intervals in the X-axis direction, and divide a part of about ¾ of the case member 50 including the end portion 50a into four divided portions 52. The four divided portions 52 are formed so as to correspond to the four switching elements.

The case member 50 has a placement surface 53a and a peripheral wall 53b. The placement surface 53a is a flat surface that faces upward and extends along the X-axis and Y-axis directions. The placement surface 53a is formed in most of the case member 50 except for a portion in the vicinity of the end portion 50a in the Y-axis direction, and is a surface that supports the pressing member 60. The peripheral wall 53b is formed so as to protrude upward from the placement surface 53a at a peripheral edge portion of the placement surface 53a. The length of the peripheral wall 53b in the Z-axis direction may be about the same as the thickness of the pressing member 60. The placement surface 53a and the peripheral wall 53b form an accommodation portion 53 having an opening portion facing upward. The accommodation portion 53 is a portion forming a region for accommodating the pressing member 60.

The case member 50 includes a plurality of (two) positioning portions 54. The plurality of positioning portions 54 correspond respectively to the plurality of pressing members 60. Each of the plurality of positioning portions 54 is provided on the placement surface 53a and protrudes upward from the placement surface 53a. For example, the plurality of positioning portions 54 are provided in portions of the placement surface 53a that form the second and fourth divided portions 52 counting from one end of the case member 50 in the X-axis direction. The positioning portions 54 may each be formed in a cylindrical shape. Each of the plurality of positioning portions 54 is a portion that regulates the position of the pressing member 60 in the X-axis and Y-axis directions.

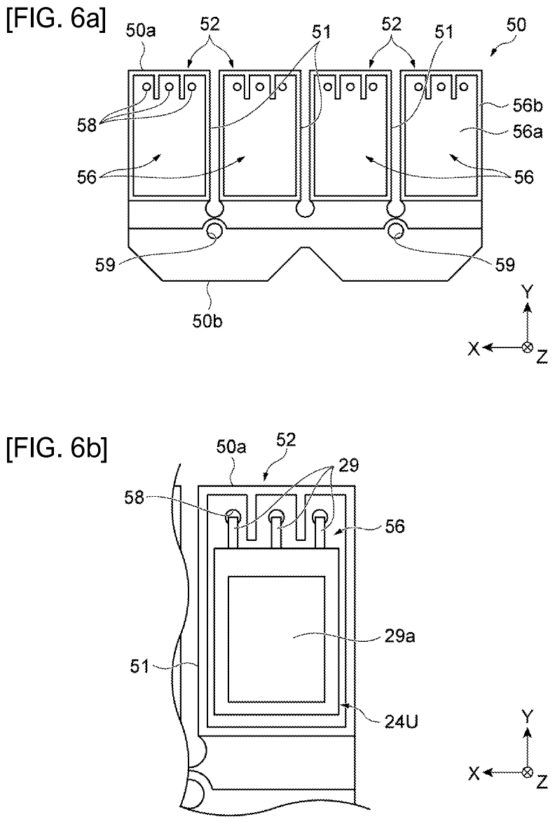

FIG. 6(a) illustrates the case member 50 as viewed from below. Each of the plurality of divided portions 52 includes a facing surface 56a and a peripheral wall 56b. The facing surface 56a is a flat surface that faces downward and extends along the X-axis and Y-axis directions. The facing surface 56a is in contact with the main body portion of the switching element while facing the main body portion. The peripheral wall 56b is formed so as to protrude downward from the facing surface 56a at a peripheral edge portion of the facing surface 56a. The facing surface 56a and the peripheral wall 56b of each of the plurality of divided portions 52 form an accommodation portion 56 (second accommodation portion) having an opening portion facing downward. The accommodation portion 56 is a portion forming a region for accommodating a plurality of switching elements. The accommodation portion 56 may be configured to accommodate the plurality of switching elements individually. In FIG. 6(a), a portion in which one switching element is accommodated is denoted by the reference numeral “56” that is the same as that for the accommodation portion 56. As described above, the case member 50 includes the accommodation portion 53 (first accommodation portion) and the accommodation portion 56 (second accommodation portion) having the opening portions facing opposite to each other in the Z-axis direction.

In the case member 50, a plurality of insertion holes 58 are formed in each of the plurality of divided portions 52 to be formed through the divided portion 52 in the Z-axis direction. The plurality of insertion holes 58 are located in a portion that does not overlap with the placement surface 53a (a portion in which the placement surface 53a is not formed). The plurality of insertion holes 58 are located at a distal end portion closer to the end portion 50a of the divided portion 52. The plurality of insertion holes 58 are provided so as to correspond to the plurality of lead terminals of the switching element. One of the lead terminals of the switching element is inserted into one insertion hole 58. In the Y-axis direction, the plurality of insertion holes 58 (all the insertion holes 58) formed in one divided portion 52 are formed at the same position. The positions of the plurality of insertion holes 58 in the Y-axis direction are the same between the plurality of (all) divided portions 52.

Referring back to FIG. 5, the case member 50 has a plurality of through holes 59 formed through the case member 50 in the Z-axis direction at a position where the placement surface 53a is formed. The plurality of through holes 59 correspond to the plurality of respective pressing members 60. The through holes 59 are provided for fixing the switching module 40 to the heat sink 98. The through holes 59 are formed at positions different from the slits 51 in the Y-axis direction. One through hole 59 is formed at the same position as the slit 51 that is the first from one end of the case member 50 in the X-axis direction. Another one through hole 59 is formed at the same position as the slit 51 that is third from one end of the case member 50 in the X-axis direction.

In the switching module 40, all types of switching elements included in one switch group 25U related to the U-phase 8U are packaged. Thus, in the example illustrated in FIG. 5, the four switching elements included in the switching module 40 can form one arm of the power conversion circuit 2 related to one phase (U-phase) of the three-phase alternating current. These four switching elements respectively correspond to four portions (all portions) in one arm of the three-level inverter circuit. A portion in one arm is also referred to as a switching layer.

The switching elements 21U, 22U, 23U, and 24U are disposed to face the case member 50 in the Z-axis direction in a state of being disposed along the X-axis direction. The positions of the switching elements 21U, 22U, 23U, and 24U may be the same in the Y-axis direction. For example, the switching elements 21U, 22U, 23U, and 24U are disposed side by side in this order from one end of the case member 50 in the X-axis direction. The switching elements 21U, 22U, 23U, and 24U may be provided in the accommodation portion 56. The switching elements 21U, 22U, 23U, and 24U are provided in the accommodation portion 56 so as to be individually accommodated in the four divided portions 52, for example.

The switching elements 21U, 22U, 23U, and 24U may have the same shape. Each of the switching elements 21U, 22U, 23U, and 24U includes a main body portion 28 and a plurality of (three) lead terminals 29. The main body portion 28 is formed in a rectangular parallelepiped shape. In one example, the pair of largest surfaces of the main body portion 28 are disposed along the X-axis and Y-axis directions. The main body portion 28 has a rectangular shape as viewed in the Z-axis direction, and the main body portion 28 is disposed to have the long side extending along the Y-axis direction and have the short side extending along the X-axis direction.

At least part of each of the plurality of lead terminals 29 (at least part of each lead terminal 29) is formed to extend along a direction intersecting the X-axis and Y-axis directions. In one example, the plurality of lead terminals 29 are connected to a surface of the main body portion 28 facing one side in the Y-axis direction. The lead terminal 29 includes a first portion extending along the Y-axis direction and a second portion extending along the Z-axis direction. One end of the first portion is connected to the main body portion 28, and the other end of the first portion is connected to one end of the second portion. The second portion extends upward along the Z-axis direction starting from a connection portion with the first portion.

FIG. 6(b) schematically illustrates a state in which the switching elements are provided in the accommodation portion 56. Each of the switching elements 21U, 22U, 23U, and 24U is disposed in the accommodation portion 56 (in an accommodation space formed in a lower portion of the corresponding one of the divided portions 52) in a state where the upper surface of the main body portion 28 faces the facing surface 56a of the accommodation portion 56. A portion (for example, the second portion) of each of the plurality of lead terminals 29 extending along a direction intersecting the X-axis and Y-axis directions is inserted into a corresponding one of the lead terminals 29 and placed through the case member 50. Each of the switching elements 21U, 22U, 23U, and 24U may include a terminal 29a other than the lead terminals. The terminal 29a is a terminal formed in a plate shape, and is provided on the lower surface of the main body portion 28 so as to be parallel to the lower surface of the main body portion 28. The potential of the terminal 29a may be the same as that of one of the plurality of lead terminals 29 (for example, the collector).

As illustrated in FIG. 5, the plurality of pressing members 60 are disposed side by side along the X-axis direction. The pressing member 60 is a member configured to press at least part of each of the switching elements 21U, 22U, 23U, and 24U toward one side (downward) in the Z-axis direction via the case member 50. One pressing member 60 may be formed to be configured to press two or more of the switching elements 21U, 22U, 23U, and 24U. In the example illustrated in FIG. 5, one pressing member 60 is configured to press the switching elements 21U and 22U via the case member 50. The other pressing member 60 is configured to press the switching elements 23U and 24U via the case member 50.

The pressing member 60 is a metal (sheet metal) formed in a plate shape so as to extend in the X-axis and Y-axis directions. At least part of the pressing member 60 is formed so as to function as a plate spring, so that external force can be applied to the switching element via the case member 50. The pressing member 60 may be formed in a U shape in plan view. The pressing member 60 includes, for example, a connection portion 62 and two pressing portions 64.

The connection portion 62 is a portion connecting the two pressing portions 64 to each other. The connection portion 62 is formed in a rectangular shape on the whole so as to extend along the X-axis direction. The two pressing portions 64 are configured to press the two switching elements, respectively. The two pressing portions 64 are connected to the connection portion 62 in a state of being separated from each other in the X-axis direction. Each of the two pressing portions 64 is formed so as to extend along the Y-axis direction starting from one end (an end portion close to the end portion 50a) of the connection portion 62 in the Y-axis direction. The pressing portion 64 functions as a plate spring having one end supported by the connection portion 62. The thickness (the size in the Z-axis direction) of the connection portion 62 may be larger than the thickness of the pressing portion 64. The pressing portion 64 may be formed of one sheet metal, and the connection portion 62 may be formed of two sheet metals stacked on each other.

The pressing member 60 may be provided in the accommodation portion 53 so as to be supported by the placement surface 53a of the case member 50. A positioning hole 66 is formed in one of the two pressing portions 64. The positioning hole 66 is formed through the pressing portion 64 (main body portion of the pressing portion 64) in the Z-axis direction. The positioning hole 66 has a shape corresponding to the positioning portion 54 provided on the placement surface 53a. For example, with the cylindrical positioning portion 54 inserted into the circular positioning hole 66, the position of the pressing member 60 is regulated in the X-axis and Y-axis directions.

One pressing member 60 is provided in the accommodation portion 53 (supported by the placement surface 53a) such that the two pressing portions 64 correspond to the two divided portions 52 that are the first and second portions from one end of the case member 50 in the X-axis direction. The single pressing member 60 presses each of the switching elements 21U and 22U. Another one pressing member 60 is provided in the accommodation portion 53 (supported by the placement surface 53a) such that the two pressing portions 64 correspond to the two divided portions 52 that are the third and fourth portions from one end of the case member 50 in the X-axis direction. The other one pressing member 60 presses each of the switching elements 23U and 24U.

A through hole 69 (through portion) is formed in the connection portion 62 so as to be penetrate through the connection portion 62 in the Z-axis direction. The through hole 69 is provided for fixing the switching module 40 to the heat sink 98. Instead of the through hole 69 having a hole shape, a notch may be formed as the through portion in the connection portion 62. The through hole 69 may be provided at the center of the connection portion 62 in the X-axis direction, or may be positioned between the two pressing portions 64 in the X-axis direction. The through hole 69 is provided so as to correspond to one of the through holes 59 of the case member 50 in a plane (X-Y plane) in which the X axis and the Y axis extend. The center of the through hole 69 may substantially match the center of the corresponding one of the through holes 59. The diameter of the through hole 69 may be substantially the same as the diameter of the corresponding one of the through holes 59.

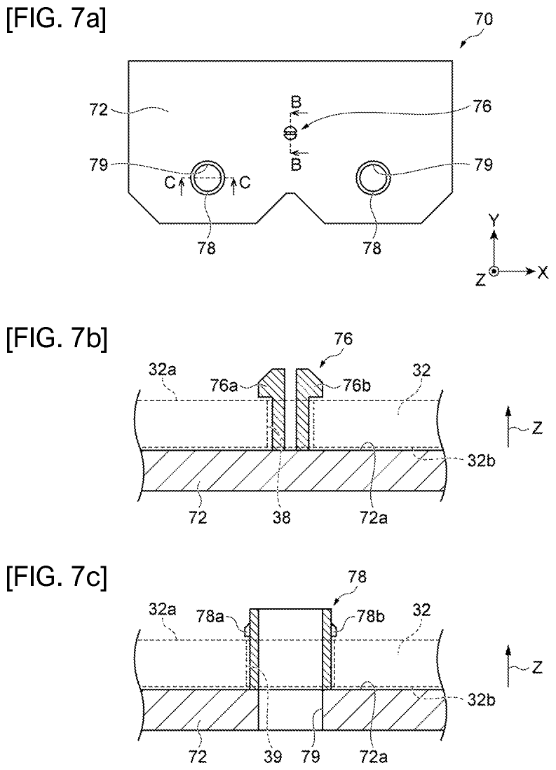

The cover member 70 is a member that maintains insulation between the pressing member 60 and the circuit board 32. The cover member 70 is attached to the case member 50 so as to cover the two pressing members 60 supported on the placement surface 53a of the case member 50. For example, the cover member 70 is formed so as to cover the entire placement surface 53a and so as not to cover a distal end portion provided with the insertion hole 58 of each of the plurality of divided portions 52. The cover member 70 is formed to extend in the X-axis and Y-axis directions on the whole. As illustrated in FIGS. 5 and 7(a), the cover member 70 has a shape corresponding to the peripheral edge portion (peripheral wall 53b) of the placement surface 53a in plan view.

The cover member 70 includes a top plate 72 and a peripheral wall 74. The top plate 72 is a portion formed so as to extend in the X-axis and Y-axis directions, and covers the placement surface 53a and the two pressing members 60 from above. The peripheral wall 74 extends downward from a peripheral edge portion of the top plate 72. The cover member 70 includes one or more fixing portions 74a extending downward from a lower end portion of the peripheral wall 74. With the fixing portion 74a fitted into a receiving portion 55 formed at a corresponding position in the case member 50, the cover member 70 is fixed to the case member 50. The peripheral wall 74 may be formed so as to surround the accommodation portion 53 (peripheral wall 53b) of the case member 50 in a state where the cover member 70 is fixed (attached) to the case member 50.

The cover member 70 has two through holes 79 formed through the top plate 72 in the Z-axis direction. The through hole 79 is provided for fixing the switching module 40 to the heat sink 98. Each of the two through holes 79 is provided so as to correspond to one of the through holes 59 of the case member 50 and one of the through holes 69 of the pressing member 60 in the X-Y plane. The center of the through hole 79 may substantially match the center of the corresponding one of the through holes 59 and the center of the corresponding one of the through holes 69. The diameter of the through hole 79 may be larger than the diameter of the corresponding one of the through holes 59, and may be larger than the diameter of the corresponding one of the through holes 69.

The cover member 70 includes a fixing portion 76. The fixing portion 76 is a portion that can be fitted into a hole formed in the circuit board 32 that is a member to which the switching module 40 is attached. The fixing portion 76 is provided in an upper surface 72a of the top plate 72 that is opposite to a surface (lower surface) facing the pressing member 60. The fixing portion 76 is provided at a position different from a position where the through hole 79 is provided (a portion in the vicinity of an opening edge of the through hole 79), and is located, for example, at the center of the top plate 72 in plan view. In FIG. 5, the fixing portion 76 is omitted.

For example, as illustrated in FIG. 7(b), the fixing portion 76 includes claw portions 76a and 76b formed so as to be divided into two. Each of the claw portions 76a and 76b is formed so as to extend upward from the upper surface of the top plate 72, and a portion including a distal end portion thereof is formed so as to bulge (protrude) toward the side. The claw portions 76a and 76b are fitted into corresponding ones of the through holes 38 formed in the circuit board 32. The through holes 38 of the circuit board 32 open at the front surface 32a and the back surface 32b. The size of bulging portions of the claw portion 76a and the claw portion 76b is larger than the diameter of the through hole 38.

The claw portion 76a and the claw portion 76b are inserted into the through holes 38 from the back surface 32b side, and the bulging portion protrudes from the front surface 32a, so that the claw portion 76a and the claw portion 76b are caught by a portion of the circuit board 32 near the opening edges of the through holes 38. Thus, even when an external force acts on the switching module 40 in a direction away from the circuit board 32, the claw portions 76a and 76b are in contact with the portions in the vicinity of the opening edges of the through holes 38. With the fixing portion 76 including the claw portion 76a and the claw portion 76b fitted into the through holes 38 formed in the circuit board 32, the movement of the switching module 40 with respect to the circuit board 32 is restricted. Thus, the switching module 40 is held by the circuit board 32.

The cover member 70 includes two tubular portions 78. The two tubular portions 78 are provided so as to correspond to the two through holes 79. In plan view, the tubular portion 78 is formed so as to surround the through hole 79 opposite thereto. The tubular portion 78 extends upward from the upper surface 72a of the top plate 72. A hole that has the same diameter as the through hole 79 and that is flush with the inner wall surface of the through hole 79 is formed inside the tubular portion 78. In the following description, in order to simplify the description, it is assumed that the through hole 79 includes a hole inside the tubular portion 78 in addition to a portion formed through the top plate 72. The tubular portion 78 is inserted into a through hole 39 formed in the circuit board 32 when the switching module 40 is attached to the circuit board 32. The through hole 39 of the circuit board 32 opens at the front surface 32a and the back surface 32b. The tubular portion 78 has a function of maintaining insulation between a member disposed in the through hole 79 for fixing the switching module 40 to the heat sink 98 and an electronic component mounted on the circuit board 32.

As illustrated in FIG. 7(c), protruding portions 78a and 78b protruding outward may be provided on the outer peripheral surface of each of the two tubular portions 78. The protruding portion 78a and the protruding portion 78b may be disposed on a virtual straight line passing through the center of the through hole 79 in plan view. The distance between the outermost portion of the protruding portion 78a and the outermost portion of the protruding portion 78b is larger than the diameter of the through hole 39 of the circuit board 32. As in the case of fitting the claw portions 76a and 76b, the tubular portion 78 is inserted into the through hole 39 of the circuit board 32 from the back surface 32b side, and the protruding portions 78a and 78b protrude from the front surface 32a, so that the protruding portions 78a and 78b are caught in the portion in the vicinity of the opening edge of the through hole 39. With the tubular portion 78 including the protruding portions 78a and 78b fitted into the through hole 38 formed in the circuit board 32, the movement of the switching module 40 with respect to the circuit board 32 is restricted. Specifically, the tubular portions 78 including the protruding portions 78a and 78b form a fixing portion that can be fitted into the through hole 38 formed in the circuit board 32, and with this configuration, the switching module 40 is held by the circuit board 32.

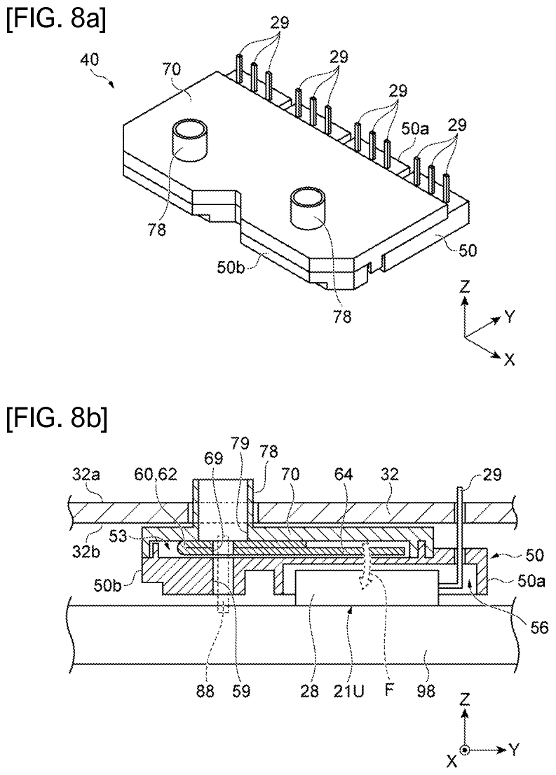

FIG. 8(a) illustrates the switching module 40 in an assembled state, and FIG. 8(b) illustrates a cross section of the switching module 40 in the Y-Z plane. FIG. 8(b) schematically illustrates a cross section of a portion in which the through holes 69 are formed and a cross section of a portion in which the switching elements 21U are accommodated, which are located at different positions in the X-axis direction. The switching elements 21U, 22U, 23U, and 24U are disposed closer to the end portion 50a that is one of both end portions of the case member 50 in the Y-axis direction. In other words, in the cross-sectional view of the switching module 40 in the Y-Z plane, the switching elements 21U, 22U, 23U, and 24U are located closer to the end portion 50a between the end portion 50b and the end portion 50a. The switching module 40 does not have a switching element disposed closer to the end portion 50b which is the other end portion of both end portions of the case member 50.

Regarding the switching element 21U, the shortest distance between the end portion 50a and the switching element 21U in the Y-axis direction is shorter than the shortest distance between the end portion 50b and the switching element 21U in the Y-axis direction. Regarding the switching elements 22U, 23U, and 24U, the relationship between the distance from the end portion 50a and the distance from the end portion 50b is the same as the corresponding relationship in the switching elements 21U.

Portions extending along the Z-axis direction of the respective lead terminals 29 of the switching elements 21U, 22U, 23U, and 24U are exposed on the upper surface side of the case member 50. At least part of each of the plurality of lead terminals 29 of the switching element 21U is electrically connected to the circuit board 32 by soldering or the like. Similarly, at least part of each of the plurality of lead terminals 29 of the switching elements 22U, 23U, and 24U is electrically connected to the circuit board 32 by soldering or the like. As described above, one or more lead terminals 29 included in each of the switching elements 21U, 22U, 23U, and 24U are electrically connected to the circuit board 32. In the Z-axis direction, the distal end portions (upper end portions) of the lead terminals 29 of the switching elements 21U, 22U, 23U, and 24U may be higher than the top plate 72 of the cover member 70.

As illustrated in FIG. 8(b), the through hole 59 of the case member 50, the through hole 69 of the pressing member 60, and the through hole 79 of the cover member 70 overlap each other, and form one hole formed through the switching module 40 in the Z-axis direction. The through holes 59, 69, and 79 are located between the switching elements 21U, 22U, 23U, and 24U and the end portion 50b in the Y-axis direction. In plan view, none of the through hole 59, the through hole 69, and the through hole 79 overlaps the switching elements 21U, 22U, 23U, and 24U. The through hole 59, the through hole 69, and the through hole 79 may be located closer to the end portion 50b between the end portion 50a and the end portion 50b. Regarding each of the through hole 59, the through hole 69, and the through hole 79, the shortest distance between the end portion 50b and the through hole in the Y-axis direction may be smaller than the shortest distance between the end portion 50a and the through hole in the Y-axis direction.

Regarding one switching element (for example, the switching element 21U), the end portion 50a, the plurality of lead terminals 29, the main body portion 28, and the through hole 69 may be disposed in this order in the Y-axis direction. The through hole 69 is provided on the side opposite to the side provided with the lead terminal 29 in the Y-axis direction. Also in the other switching elements (for example, each of the switching elements 22U, 23U, and 24U), the end portion 50a, the plurality of lead terminals 29, the main body portion 28, and the through hole 69 may be disposed in this order in the Y-axis direction.

The switching module 40 includes a fixing member 88. The fixing member 88 is a member for fixing the switching module 40 to the heat sink 98. The fixing member 88 is, for example, a screw, and most of the fixing member 88 (screw portion) is disposed in the through hole 69 and the through hole 59. A screw hole may be formed in a surface of the heat sink 98 facing the switching module 40. The screw head of the fixing member 88 may be located above the connection portion 62 of the pressing member 60 and may be in contact with the upper surface of the connection portion 62 in the through hole 79. The switching module 40 is fixed to the heat sink 98 in a state of being connected to the circuit board 32 by soldering at the lead terminal 29, the fixing portion 76, and the like. Thus, the switching module 40 is fixed to the heat sink 98 together with the circuit board 32.

With the switching module 40 fixed to the heat sink 98 by the fixing member 88, a downward force acts on the case member 50 by the spring force of the plate spring in the pressing portion 64. Thus, the pressing member 60 applies a force F to the corresponding one of the switching elements 21U, 22U, 23U, and 24U in a direction toward the heat sink 98. Due to the fixing by the fixing member 88, each of the switching elements such as the switching element 21U is in a state of being pressed toward the heat sink 98 (a state of being in close contact with the heat sink 98), so that the heat of the switching module 40 including the switching elements 21U and the like can be more reliably dissipated. The switching elements such as the switching elements 21U are in close contact with the heat sink 98 via the insulating sheet 96 that is not illustrated in FIG. 8(b).

As illustrated in FIG. 4, when the arm related to the U-phase 8U includes the plurality of switch groups 25U, a plurality of the switching modules 40 each including the switch group 25U are provided on the circuit board 32. When the arm related to the W-phase 8W includes the plurality of switch groups 25W, a plurality of the switching modules 40 each including the switch group 25W are provided on the circuit board 32. Hereinafter, the switching module 40 including the switch group 25U is referred to as a “switching module 40U”, and the switching module 40 including the switch group 25W is referred to as a “switching module 40W”. For example, three switching modules 40U and three switching modules 40W are provided on the back surface 32b of the circuit board 32. When the power conversion circuit 2 includes a boost circuit (DC-DC converter), the switching module 40 including a plurality of switching elements forming the boost circuit may be provided on the circuit board 32 in addition to the switching modules 40U and 40W.

The plurality of switching modules 40U are disposed side by side in one direction (X-axis direction) along the back surface 32b of the circuit board 32. The plurality of switching modules 40U are disposed such that the switching elements 21U, 22U, 23U, and 24U included in the respective modules are disposed in the X-axis direction. The positions in the Y-axis direction (mounting positions on the circuit board 32) may be the same among the plurality of switching modules 40U. Regarding one switching module 40U, portions of all the lead terminals 29 along the Z-axis direction may be disposed on a virtual line extending in the X-axis direction in plan view. Regarding the plurality of switching modules 40U, the portions along the Z-axis direction of all the lead terminals 29 included in the plurality of switching modules 40U may be disposed on the virtual line extending in the X-axis direction in plan view. The plurality of portions being disposed on the virtual line extending in the X-axis direction does not mean that the plurality of portions are disposed on a straight line in a strict sense, and it is only necessary that at least parts of the plurality of respective portions are located at the same position in the Y-axis direction.

Each of the plurality of switching modules 40U may be disposed closer to one end portion 32c of both end portions of the circuit board 32 in the Y-axis direction. The distance between the switching elements such as the switching elements 21U and the end portion 32c in the Y-axis direction may be shorter than the distance between the through hole 69 (or the corresponding through hole 39) and the end portion 32c in the Y-axis direction. The plurality of sets of through holes 39 corresponding to the plurality of switching modules 40U are formed side by side on the virtual line along the X-axis direction.

The plurality of switching modules 40W are disposed side by side in one direction (X-axis direction) along the back surface 32b of the circuit board 32. The plurality of switching modules 40W are disposed such that the switching elements 21W, 22W, 23W, and 24W included in the respective modules are disposed in the X-axis direction. The positions in the Y-axis direction (mounting positions on the circuit board 32) may be the same among the plurality of switching modules 40W. Regarding one switching module 40W, portions of all the lead terminals 29 along the Z-axis direction may be disposed on a virtual line extending in the X-axis direction in plan view. Regarding the plurality of switching modules 40W, the portions along the Z-axis direction of all the lead terminals 29 included in the plurality of switching modules 40W may be disposed on the virtual line extending in the X-axis direction in plan view.

Each of the plurality of switching modules 40W may be disposed closer to the other end portion 32d of both end portions of the circuit board 32 in the Y-axis direction. The distance between the switching elements such as the switching elements 21W and the end portion 32d in the Y-axis direction may be shorter than the distance between the through hole 69 (or the corresponding through hole 39) and the end portion 32d in the Y-axis direction. The plurality of sets of through holes 39 corresponding to the plurality of switching modules 40W are formed side by side on the virtual line along the X-axis direction.

The plurality of switching modules 40W may be respectively disposed at the same positions as the plurality of switching modules 40U in the X-axis direction. In the Y-axis direction, a region is provided on the circuit board 32 between one switching module 40U and a corresponding one of the switching modules 40W. In the Y-axis direction, the end portion 32c, the switching elements 21U and the like, the through hole 69 of the switching module 40U, the through hole 69 of the switching module 40W, the switching elements 21W and the like, and the end portion 32d may be disposed in this order. In FIG. 4, the position of the through hole 39 corresponds to the position of a corresponding one of the through holes 69.

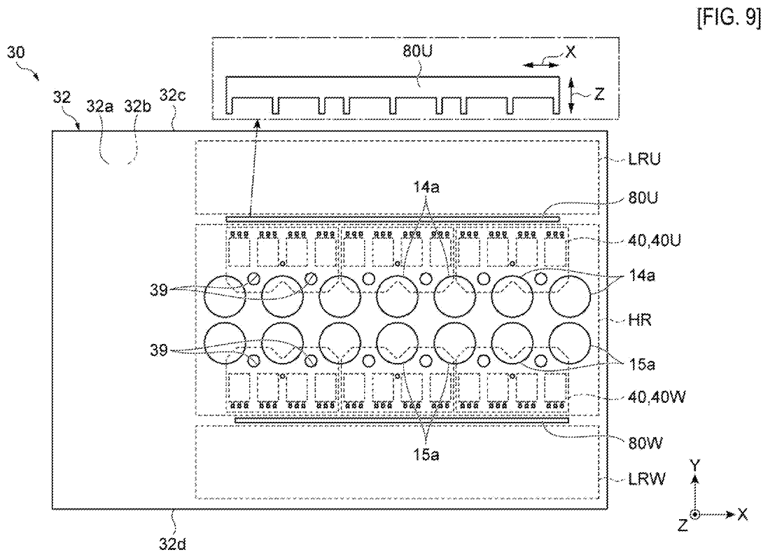

As illustrated in FIG. 9, the first capacitor 14 and the second capacitor 15 (see FIG. 1) included in the power conversion circuit 2 are provided on the front surface 32a (first principal surface) of the circuit board 32. FIG. 9 illustrates an example of a case where the first capacitor 14 in the power conversion circuit 2 includes a plurality of capacitors connected in parallel to each other, and each of the plurality of capacitors forming the first capacitor 14 is denoted by a reference sign “14a”. Thus, the circuit body 30 includes the plurality of capacitors 14a provided on the front surface 32a.

The capacitor 14a is electrically connected to one or more switching elements included in the switching module 40U and/or the switching module 40W via a wiring pattern formed on the circuit board 32. For example, the capacitor 14a is electrically connected to the switching elements 21U and 22U and the switching elements 21W and 22W via the wiring pattern. When viewed from a direction orthogonal to the front surface 32a (in plan view), at least part of the capacitor 14a is disposed to overlap the switching module 40U. Regarding at least some of the capacitors 14a among the plurality of capacitors 14a, at least part of the capacitor 14a may overlap any of the switching modules 40U in plan view. In the example illustrated in FIG. 9, one or more other capacitors 14a forming the first capacitor 14 may be provided at a position not overlapping the switching module 40U.

The plurality of capacitors 14a may be disposed on a virtual line extending in the X-axis direction. The plurality of capacitors 14a may be disposed at equal intervals. The position of at least part of each of the plurality of capacitors 14a in the Y-axis direction may be the same as the position of at least part of the switching module 40U in the Y-axis direction. In one example, at least part of the second, fourth, or sixth capacitor 14a from the right on the paper plane of FIG. 9 in the X-axis direction is disposed between the two through holes 39 (or the two through holes 69) corresponding to one switching module 40U. In the X-axis direction, at least part of each of the third and fifth capacitors 14a from the right on the paper plane of FIG. 9 is disposed between the through hole 39 corresponding to one switching module 40U and the through hole 39 corresponding to another switching module 40U adjacent to the module.

In FIG. 9, each of the plurality of capacitors forming the second capacitor 15 in the power conversion circuit 2 and connected in parallel to each other is denoted by a reference sign “15a”. Thus, the circuit body 30 includes the plurality of capacitors 15a provided on the front surface 32a. The capacitor 15a is electrically connected to one or more switching elements included in the switching module 40U and/or the switching module 40W via a wiring pattern formed on the circuit board 32. For example, the capacitor 15a is electrically connected to the switching elements 22U and 24U and the switching elements 22W and 24W via the wiring pattern. The plurality of capacitors 15a may be disposed on a virtual line extending in the X-axis direction. In the X-axis direction, the positions of the plurality of capacitors 15a may respectively correspond to (substantially match) the positions of the plurality of capacitors 14a. In the Y-axis direction, a gap is provided between one capacitor 15a and a corresponding one of the capacitors 14a. The relationship among the plurality of capacitors 15a, the plurality of switching modules 40W, and the plurality of through holes 39 corresponding to the switching modules 40W may be the same as the relationship among the plurality of capacitors 14a, the plurality of switching modules 40U, and the plurality of through holes 39 corresponding to the switching modules 40U.

The circuit body 30 includes a bus bar 80U and a bus bar 80W. The bus bars 80U and 80W are metallic wiring members forming part of the main circuit of the power conversion circuit 2. The bus bar 80U is electrically connected to the lead terminals 29 for the main circuit in the power conversion circuit 2, included in one or more of the switching elements 21U, 22U, 23U, and 24U. The bus bar 80U forms, for example, part of a circuit between the connection point 17U and the U-phase 8U in the power conversion circuit 2. The bus bar 80U may electrically connect the plurality of lead terminals 29 that are included in the plurality of switching modules 40U and that are to be at the same potential as each other.

The bus bar 80W is electrically connected to the lead terminals 29 for the main circuit in the power conversion circuit 2, included in one or more of the switching elements 21W, 22W, 23W, and 24W. The bus bar 80W forms, for example, part of a circuit between the connection point 17W and the W-phase 8W in the power conversion circuit 2. The bus bar 80W may electrically connect the plurality of lead terminals 29 that are included in the plurality of switching modules 40W and that are to be at the same potential as each other.

Each of the bus bars 80U and 80W is provided on the front surface 32a of the circuit board 32 in a state of intersecting the front surface 32a. The main body portion of each of the bus bars 80U and 80W extends in a direction orthogonal to the front surface 32a, for example, as illustrated in the drawing in the region surrounded by a one dot chain line in FIG. 9. The main body portion of each of the bus bars 80U and 80W may be formed to extend in the X-axis direction. The bus bars 80U and 80W may be electrically connected to the lead terminals 29 via the wiring pattern of the circuit board 32, or may be connected to the lead terminals 29 without the wiring pattern in between.

The circuit board 32 is partitioned into a high-voltage region and a low-voltage region with a virtual line (hereinafter referred to as “first virtual line”) extending along the X-axis direction in the vicinity of one or more lead terminals 29 of each of the switching elements 21U, 22U, 23U, and 24U serving as a boundary. The virtual line located in the vicinity of one or more lead terminals 29 overlaps at least part of the lead terminal 29 in plan view, or is separated from the lead terminal 29 in the Y-axis direction by a distance equal to or less than the size of the main body portion 28 in the Y-axis direction. With the virtual line serving as the boundary, the high-voltage region is provided on one side of the virtual line in the Y-axis direction, and the low-voltage region is provided on the other side of the virtual line. The high-voltage region is a region where a main circuit (a circuit through which a current converted from a direct current to an alternating current flows) of the power conversion circuit 2 is formed. The low-voltage region is a region in which components that operate at a lower voltage than the main circuit are disposed.

In the low-voltage region, for example, various components for generating a gate drive signal for switching the open/close state of the switching element are disposed. In the high-voltage region, part of a wiring pattern through which a current flows from a component operating at a lower voltage than the main circuit of the power conversion circuit 2 may be disposed. For example, part of the wiring pattern through which the current for the gate drive signal flows may be formed to extend to the connection portion of the lead terminal 29 in the high-voltage region. The partitioning into the high-voltage region and the low-voltage region may be performed with a virtual line (hereinafter referred to as “second virtual line”) extending along the X-axis direction also in the vicinity of one or more lead terminals 29 of each of the switching elements 21W, 22W, 23W, and 24W serving as a boundary.

In the example illustrated in FIG. 9, a low-voltage region LRU and a high-voltage region HR are partitioned by the first virtual line serving as a boundary, and a low-voltage region LRW and the high-voltage region HR are partitioned by the second virtual line serving as a boundary. For example, electronic components for generating the gate drive signal to the switching elements 21U, 22U, 23U, and 24U are disposed in the low-voltage region LRU. For example, electronic components for generating the gate drive signal to the switching elements 21W, 22W, 23W, and 24W are disposed in the low-voltage region LRW. In the high-voltage region HR, the plurality of capacitors 14a and the plurality of capacitors 15a, as well as the plurality of switching modules 40U and the plurality of switching modules 40W described above are disposed, and the wiring pattern for the main circuit of the power conversion circuit 2 is formed.

In the Y-axis direction, the low-voltage region LRU, the high-voltage region HR, and the low-voltage region LRW are disposed in this order. The bus bar 80U is disposed between the low-voltage region LRU and the high-voltage region HR. That is, the bus bar 80U provided on the front surface 32a is located on the first virtual line. For example, the first virtual line is set so as to overlap the bus bar 80U in plan view. The bus bar 80W is disposed between the low-voltage region LRW and the high-voltage region HR. That is, the bus bar 80W provided on the front surface 32a is located on the second virtual line. For example, the second virtual line is set to overlap the bus bar 80W in plan view.

A range (a range in the X-axis direction) that is partitioned into the low-voltage region LRU and the high-voltage region HR includes at least a range from one end to the other end of the plurality of switching modules 40U in the X-axis direction. Other than the range from one end to the other end of the plurality of switching modules 40U in the X-axis direction, a region may be partitioned in any manner. In one example, the range in the X-axis direction matches a range from one end to the other end of the plurality of switching modules 40U in the X-axis direction, and the low-voltage region is not provided but the high-voltage region is provided in a range other than the range from one end to the other end of the plurality of switching modules 40U in the X-axis direction.

### Manufacturing Process for Power Conversion Device

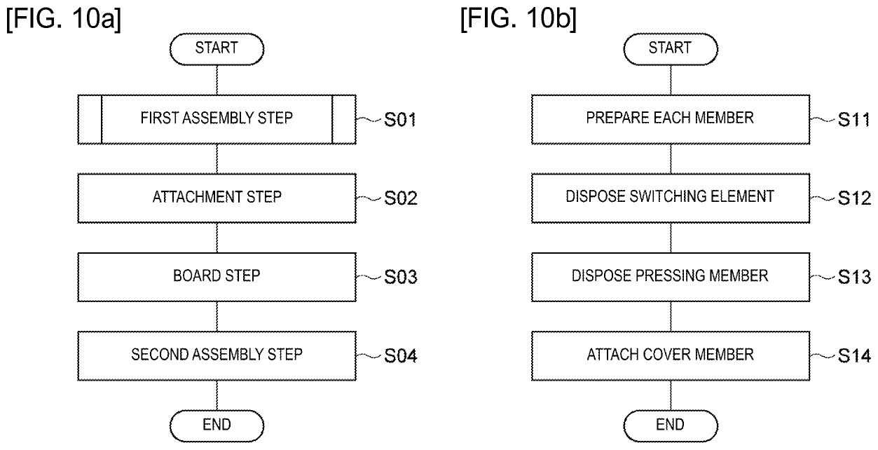

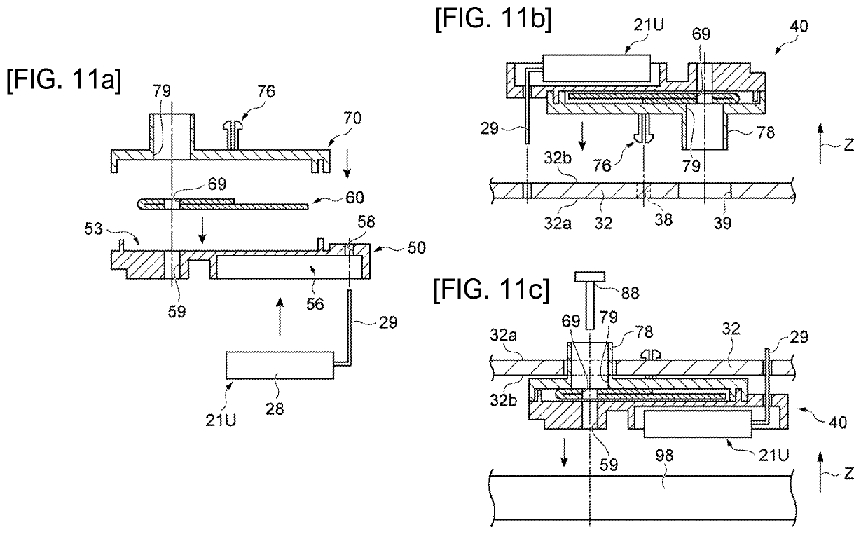

Next, an example of a manufacturing process for the power conversion device 1 (a manufacturing method for the power conversion device) will be described with reference to FIGS. 10 and 11. The manufacturing process for the power conversion device 1 includes, for example, a first assembly step, an attachment step, a board step, and a second assembly step. FIG. 10(a) is a flowchart illustrating an example of a manufacturing process for the power conversion device 1. As illustrated in FIG. 10(a), the first assembly step, the attachment step, the board step, and the second assembly step are executed in this order. At least some of these steps may be performed manually, or at least some of these steps may be performed automatically by an apparatus. A case of manufacturing the power conversion device 1 including the switching module 40 illustrated in FIG. 5 and the like will be described below.

In the first assembly step (step S01), the above-described switching module 40 is assembled. Assembling the switching module 40 means that various members included in the switching module 40 are assembled together. FIG. 10(b) is a flowchart illustrating an example of the first assembly step. As illustrated in FIG. 10(b), in the first assembly step, first, various members forming the switching module 40 are prepared (step S11). The preparation of the various members includes preparing a plurality of switching elements, preparing the case member 50 formed so as to extend in two directions orthogonal to each other, and preparing the pressing member 60 having the through hole 69 formed therein.

Next, as illustrated in FIG. 11(a) or FIG. 5, the switching elements 21U, 22U, 23U, and 24U are disposed as a plurality of switching elements in the accommodation portion 56 of the case member 50 (step S12). When the plurality of switching elements are disposed, the plurality of switching elements are disposed in one direction (the X-axis direction in FIG. 5) of the two directions in which the case member 50 extends, and the plurality of switching elements face the case member 50 in a direction (the stacking direction) orthogonal to the two directions. The plurality of switching elements are disposed closer to the end portion 50a of the case member 50 in the other direction (the Y-axis direction in FIG. 5) of the two directions. When the switching elements are disposed in the accommodation portion 56, the plurality of lead terminals 29 of the switching elements are inserted into the plurality of insertion holes 58 connected by the one dot chain line in FIG. 5.

Next, as illustrated in FIG. 11(a) or FIG. 5, the pressing member 60 is disposed in the accommodation portion 53 of the case member 50 (step S13). For example, the pressing member 60 is disposed in the accommodation portion 53 so that the positioning hole 66 of the pressing member 60 is inserted into the positioning portion 54 connected by the one dot chain line in FIG. 5. As a result, the pressing member 60 (part of the pressing member 60) overlaps the two or more switching elements via the case member 50 in the stacking direction. In addition, the through hole 59 of the pressing member 60 is positioned between the end portion 50b of the case member 50 and each of the switching elements in the other direction (the Y-axis direction in FIG. 5) of the two directions. Then, the cover member 70 is attached to the case member 50 so as to cover the pressing member 60 (step S14). For example, the cover member 70 is attached to the case member 50 such that the fixing portion 74a formed in the cover member 70 is fitted into the receiving portion 55 connected by the one dot chain line in FIG. 5. One switching module 40 is assembled through the step described above. The other plurality of switching modules 40 are assembled in the same manner.

In the attachment step (step S02), the switching module 40 is mounted on the circuit board 32. In the attachment step, as illustrated in FIG. 11(b), each of the plurality of switching modules 40 (for example, the plurality of switching modules 40U and the plurality of switching modules 40W) is attached to the back surface 32b of the circuit board 32 from above in a state where the back surface 32b of the circuit board 32 faces upward. In one example, the fixing portion 76 of the switching module 40 is inserted and fitted in the through hole 38 of the circuit board 32, and the tubular portions 78 including the protruding portion 78a and the protruding portion 78b are inserted and fitted in the through holes 39 of the circuit board 32. Thus, the switching module 40 is held by the circuit board 32. When the switching module 40 is attached to the back surface 32b, the plurality of lead terminals 29 of the switching elements are inserted into the through holes of the circuit board 32. The attachment of the switching module 40 on the circuit board 32 corresponds to the temporary fixing of the switching module 40 because the lead terminals 29 are not soldered.

In the board step (step S03), the circuit board 32 is soldered. In one example, the circuit board 32 (an intermediate of the circuit body 30) to which the plurality of switching modules 40 are attached is inverted so that the front surface 32a faces upward (see FIG. 11(c)). Then, in a state where the plurality of capacitors 14a, the plurality of capacitors 15a, the bus bars 80U and 80W, and other various electronic components are placed on the front surface 32a, these components are soldered. In the board step, at least part of each of the plurality of lead terminals 29 of each switching element may be electrically connected to the circuit board 32 by soldering. The circuit body 30 may be formed by performing the board step.

In the second assembly step (step S04), as illustrated in FIG. 11(c), the switching module 40 attached to the circuit board 32 is fixed to the heat sink 98. In one example, in the second assembly step, the circuit body 30 is placed on the heat sink 98 from above such that the plurality of switching elements (accommodation portion 56) and the back surface 32b of the circuit board 32 face the heat sink 98 and the plurality of switching elements are supported by the heat sink 98. Then, the fixing member 88 is inserted (disposed) into a region including the through hole 79, the through hole 69, and the through hole 59 from the opening at the upper end of the tubular portion 78 fitted in the through hole 39 of the circuit board 32.

Thereafter, in the second assembly step, each switching module 40 is fixed to the heat sink 98 together with the circuit board 32 by the fixing member 88 disposed in at least the through hole 69 (the through hole 69 of the pressing member 60) so that at least part of each of the plurality of switching elements is pressed toward the heat sink 98 by the pressing member 60. At least part each of the plurality of lead terminals 29 of each switching element may be electrically connected to the circuit board 32 by soldering after the second assembly step, instead of performing the soldering of the lead terminals in the board step. In the second assembly step, while the circuit body 30, the insulating sheet 96, and the heat sink 98 are fixed to the housing 92 illustrated in FIG. 3, the switching module 40 and the circuit board 32 may be attached to the heat sink 98. After the above-described steps, the other members may be disposed in the housing 92, and the housing 92 may be closed by the cover 94 to form the power conversion device 1.

### Modified Examples

The switching module 40, the power conversion device 1, and the manufacturing process for the power conversion device 1 described above are examples, and can be appropriately changed.

The switching circuit 20 may be an inverter circuit of a three-level neutral point clamp system (NPC system) instead of the three-level bidirectional switch system. The switching circuit 20 may be a two-level inverter circuit instead of the three-level inverter circuit. In the case where the switching circuit 20 is a two level inverter circuit, one switching module 40 may include two switching elements configured to form one arm (which are minimum units of one arm).

Each of the plurality of (all) switching elements included in one switching module 40 may be an element disposed at a corresponding portion of the arm in the power conversion circuit 2. In this case, in one switching module 40, a plurality of switching elements disposed in mutually corresponding portions (switching layer) of the arm in the power conversion circuit 2 may be packaged. The plurality of switching elements disposed at mutually corresponding portions may be included in the same one arm, or may be included in two or more arms having different related phases. In one example, in one switching module 40, the plurality of switching elements 21U included in a plurality of switch groups 25U forming an arm related to the U-phase 8U may be packaged. Alternatively, in one switching module 40, the switching element 21U and the switching element 21W with different related phases of three-phase alternating current may be packaged.

In one switching module 40, instead of the plurality of switching elements, one (single) switching element may be packaged together with other members. In this case, one switching element is disposed closer to the end portion 50a in the Y-axis direction. The pressing member 60 is formed so as to be configured to press one switching element via the case member 50.

When the switching module 40 includes a plurality of switching elements, the pressing member 60 may be configured to press one switching element via the case member 50 instead of the two switching elements. When four switching elements are included in one switching module 40, four pressing members 60 that individually press the switching elements may be provided. One pressing member 60 may be configured to press three or more switching elements via the case member 50.

The pressing member 60 need not be provided with the through portion such as the through hole 69. In this case, the pressing member 60 may be held so as to press the switching element by fixing means (for example, pressing by the cover member 70) other than the fixing member such as a screw disposed in the through portion such as the through hole 69. In one of the various examples described above, at least some of the matters described in another example may be applied.

Note that in a case where “parallel”, “flat/planar”, “orthogonal” and the like are used in the description above, the meanings are not construed strictly. That is, “parallel”, “flat/planar”, and “orthogonal” mean “substantially parallel”, “substantially flat/planar”, and “substantially orthogonal” respectively, with allowance for design and manufacturing tolerances and errors. Also, in a case where “the same”, “identical”, “equal”, “different” and the like are used in the description above with reference to the external dimensions and size, the shape, the position, or the like, the meanings are not construed strictly. That is, “the same”, “equal”, and “different” mean “substantially the same”, “substantially equal”, and “substantially different”, respectively, with allowance for design and manufacturing tolerances and errors.

### Supplement

The present disclosure includes configurations described in the following (1) to (18).

(1) A switching module 40 for use in a power conversion circuit 2, including: a case member 50 formed to extend in X-axis and Y-axis directions orthogonal to each other; one or more switching elements disposed to face the case member 50 in a stacking direction (Z-axis direction) orthogonal to the X-axis and Y-axis directions; and a pressing member 60 configured to press at least part of the one or more switching elements toward one side in the stacking direction via the case member 50, in which the one or more switching elements are disposed closer to one end portion (end portion 50a) of both end portions of the case member 50 in the Y-axis direction.

In the switching module 40, since the switching elements are pressed by the pressing member 60 via the case member 50, the insulation between the pressing member 60 and the switching elements is more reliably maintained. The switching element disposed closer to one side in the second direction, makes it easier for the pressing member 60 to have a simple shape. Therefore, the switching module 40 can be reduced in size. Therefore, the switching module 40 is useful for reducing the size of the device.

(2) The switching module 40 according to (1) described above, in which the pressing member 60 has a through portion formed to be located between another end portion (end portion 50b) of both end portions and the one or more switching elements in the Y-axis direction, and to fix the switching module 40.

In this case, when the switching module 40 is attached to the circuit board 32, a region of the circuit board 32 that overlaps the switching module 40 can be divided into a region in which the switching elements are disposed and a region around the through portion (for example, the through hole 69) in the second direction. Since the layout of the component arrangement, the wiring pattern, and the like of the circuit board 32 is affected by the position of the switching element and the position of the through portion, the above-described configuration facilitates the layout on the circuit board 32.

(3) The switching module 40 according to (1) or (2) described above, in which the one or more switching elements are a plurality of switching elements, and the plurality of switching elements are disposed side by side along the X-axis direction. When the through portion of the pressing member is disposed between the switching elements adjacent to each other, it is necessary to increase the interval between the switching elements to maintain insulation between the switching elements and the fixing member disposed in the through portion. Further, in this case, a plurality of through portions are scattered in a circuit board to which one or more switching modules are attached, and it is difficult to use the region around the through portions as a region in which other components are disposed. On the other hand, in the switching module 40 described above, the through portion such as a through hole or a notch for fixing is provided in a region that does not overlap the switching element in the Y-axis direction, and the plurality of switching elements are collectively disposed closer to one end portion (end portion 50a) of the case member 50. Accordingly, it is possible to continuously combine the regions around the plurality of through portions in the circuit board 32, and it is easy to mount other components such as capacitors in these regions. Therefore, it is possible to reduce the component mounting region on the circuit board 32 on the whole. Therefore, the switching module 40 is useful for reducing the size of the device.

(4) The switching module 40 according to (3) described above, in which the pressing member 60 is formed to be configured to press two or more elements among the plurality of switching elements, and the pressing member 60 includes: a connection portion 62 in which the through portion is formed; and two or more pressing portions 64 configured to press the two or more elements, respectively, and connected to the connection portion 62 in a state of being separated from each other in the X-axis direction.

In this case, the through portion (for example, a through hole) for fixing each switching element need not be provided, and it is possible to suppress the component mounting region of the circuit board from being narrowed due to the provision of the through portion. In addition, a substantially constant external force can be applied to each switching element, and stable heat dissipation is possible.

(5) The switching module 40 according to any of (1) to (4) described above, in which the case member 50 includes an accommodation portion 53 and an accommodation portion 56 having opening portions facing opposite to each other in the stacking direction, the pressing member 60 is provided in the accommodation portion 53, and the one or more switching elements are provided in the accommodation portion 56.

In this case, the pressing member 60 and the one or more switching elements are accommodated in the accommodation portion 53 and the accommodation portion 56 so as to have movement restricted, and thus the displacement thereof is suppressed when the switching module 40 is attached to the other members. Thus, the configuration is effective for improving the production efficiency of the device including the switching module 40.

(6) The switching module 40 according to any of (1) to (5) described above, in which the switching element included in the one or more switching elements includes a main body portion 28 and a plurality of lead terminals 29, at least part of each of the plurality of lead terminals 29 is formed through the case member 50, and extends in a direction intersecting the X-axis and Y-axis directions, and the plurality of lead terminals 29 are disposed on a line extending in the X-axis direction.

The lead terminals 29 may be electrically connected to each other by at least one wiring member of the wiring pattern of the circuit board and the bus bar. According to the above configuration, the shape of the wiring member can be simplified.

(7) The switching module 40 according to (6) described above, in which the end portion 50a, the plurality of lead terminals 29, and the main body portion 28 are disposed in this order in the Y-axis direction.

In this case, the lead terminals 29 are disposed in the vicinity of the end portion 50a in the Y-axis direction, and it is possible to simplify the wiring pattern for the gate drive signal connected to the lead terminals 29 from the region not overlapping the switching module 40. Therefore, it is easy to divide the circuit board 32 into the high-voltage region in which the main circuit of the power conversion circuit 2 is formed and the low-voltage region in which a circuit for controlling the switching element or the like is formed, with the virtual line along the X-axis direction in the vicinity of the lead terminal 29 serving as a boundary.

(8) The switching module 40 according to any of (1) to (7) described above, further includes: a cover member 70 attached to the case member 50 so as to cover the pressing member 60.

In this case, by setting the pressing member 60 before attaching the cover member 70 while maintaining insulation between the pressing member 60 and other members such as the circuit board 32 to which the switching module 40 is attached, the operation of assembling the pressing member 60 to the case member 50 is easily performed.

(9) The switching module 40 according to (8) described above, in which the cover member 70 includes: a top plate 72 configured to cover the pressing member 60; and a fixing portion (fixing portion 76) that is provided on an upper surface 72a of the top plate 72 opposite to a surface facing the pressing member 60, and is fittable into a hole formed in a member (circuit board 32) to which the switching module 40 is attached.

In this case, in a state where the switching module 40 is temporarily fixed to the circuit board 32 by the fixing portion, an operation such as soldering can be performed on the circuit board 32 on which the switching module 40 is mounted. During an operation such as soldering, the switching module 40 is suppressed from being displaced with respect to the circuit board 32 due to the temporary fixing by the fixing portion. Thus, the configuration is effective for the improvement in the production efficiency of the device including the switching module 40.

(10) The switching module 40 according to any of (1) to (9) described above, in which the one or more switching elements are a plurality of switching elements, the power conversion circuit 2 is a conversion circuit that outputs a three-phase alternating current, and the plurality of switching elements are configured to form one arm of the power conversion circuit 2 related to one phase of the three-phase alternating current. In this case, the switching module 40 can be shared between one phase and the other phases of the three-phase alternating current. Also when the switching elements are connected in parallel in the arm of one phase, the switching module 40 can be shared. Therefore, it is effective for improving the efficiency of production of the switching module 40.

(11) The switching module 40 according to any of (1) to (9) described above, in which the one or more switching elements are a plurality of switching elements, and each of the plurality of switching elements are elements disposed at mutually corresponding portions of the arm of the power conversion circuit 2.

In this case, since the plurality of switching elements of the same type are provided in one switching module 40, the switching elements can be set in the case member 50 when assembling the switching module 40 without the need for taking the types of the elements into consideration. Therefore, this is effective for improving the efficiency of production of the switching module 40.

(12) A power conversion device 1 including: the switching module 40 according to any of (1) to (11) described above; a heat sink 98 to which the switching module 40 is fixed; and a circuit board 32 to which one or more lead terminals 29 included in the one or more switching element are electrically connected, in which the switching module 40 is fixed to the heat sink 98 together with the circuit board 32, with at least part of the one or more switching elements pressed toward the heat sink 98 by the pressing member 60.

The power conversion device 1 includes the switching module 40 according to any of (1) to (11) described above. This is effective for reducing the size of the power conversion device 1.

(13) The power conversion device 1 according to (12) described above, in which the circuit board 32 includes a front surface 32a and a back surface 32b facing opposite to each other, the power conversion device 1 device further includes a capacitor 14a provided on the front surface 32a, the switching module 40 is provided to face the back surface 32b, and at least part of a capacitor 14a is disposed to overlap the switching module 40, as viewed in a direction orthogonal to the front surface 32a. In this case, the physical distance between the switching elements and the capacitor 14a is shorter than that in the case where the capacitor 14a does not overlap the switching module 40. Therefore, the length of the wiring pattern on the circuit board 32 between the switching elements and the capacitor 14a can be made short. As a result, the wiring inductance between the switching element and the capacitor 14a can be reduced.

(14) The power conversion device 1 according to (12) or (13), in which the circuit board 32 includes the front surface 32a and the back surface 32b facing opposite to each other, the power conversion device 1 further includes a bus bar 80U electrically connected to the lead terminal 29 for a main circuit of the power conversion device 1 included in the one or more switching elements, and the bus bar 80U is provided on the front surface 32a while intersecting the front surface 32a.

Since a relatively large current flows in the main circuit of the power conversion circuit 2, the width or the like of the wiring pattern for the main circuit tends to be large. In the above-described configuration, with the bus bar 80U disposed so as to intersect the circuit board 32, the region for forming the wiring pattern for the main circuit on the circuit board 32 can be made small. Therefore, it is further effective for reducing the size of the power conversion device 1.

(15) The power conversion device 1 according to (12) or (13) described above, in which the circuit board 32 is partitioned into the high-voltage region HR and the low-voltage region LRU, with a virtual line (first virtual line) extending along the X-axis direction in a vicinity of the one or more lead terminals 29 included in the one or more switching elements and serving as a boundary, the high-voltage region HR is a region where a main circuit of the power conversion circuit 2 is formed, and the low-voltage region LRU is a region where a component operating at a lower voltage than the main circuit is disposed.

When the wiring pattern for the main circuit and the wiring pattern for low voltage coexist in a certain region of the circuit board 32, the distance between these wiring patterns needs to be set long for the sake of suppression of electromagnetic interference from the main circuit to the wiring pattern (signal) for low voltage. With the above configuration, since the high-voltage region for the main circuit and the low-voltage region are separated from each other, the electromagnetic interference can be reduced, and the wiring patterns can be somewhat densely disposed. Therefore, it is further effective for reducing the size of the power conversion device 1.

(16) The power conversion device 1 according to (15) described above, in which the circuit board 32 includes the front surface 32a and the back surface 32b facing opposite to each other, the power conversion device 1 further includes the bus bar 80U electrically connected to the lead terminal 29 for the main circuit included in the one or more switching elements, and the bus bar 80U is located on the virtual line (first virtual line) and is provided on the front surface 32a while intersecting the front surface 32a.

In this case, the high-voltage region and the low-voltage region can be more strictly separated from each other, and the electromagnetic interference can be further reduced.

(17) A manufacturing method for a power conversion device 1, the method including: a first assembling step of assembling a switching module 40; an attachment step of attaching the switching module 40 to a circuit board 32; a board step of performing soldering on the circuit board 32 after the attachment step; and a second assembly step of fixing the switching module 40 attached to the circuit board 32 to a heat sink 98 after the board step, in which the first assembly step includes: preparing one or more switching elements, a case member 50 formed to extend in a first direction and a second direction orthogonal to each other, and a pressing member 60 configured to press at least part of the one or more switching elements; disposing the one or more switching elements to be positioned closer to an end portion 50a of both end portions of the case member 50 in the second direction and to face the case member 50 in a stacking direction orthogonal to the first direction and the second direction; and disposing the pressing member 60 to overlap at least part of the one or more switching elements via the case member 50 in the stacking direction, and the second assembly step includes fixing the switching module 40 together with the circuit board 32 to the heat sink 98 such that at least part of the one or more switching elements is pressed toward the heat sink 98 by the pressing member 60.

(18) The manufacturing method according (17) described above, in which the one or more switching elements are a plurality of switching elements, the pressing member 60 has a through portion formed to fix the switching module 40, the disposing the one or more switching elements in the first assembly step includes disposing the plurality of switching elements side by side along the first direction, the disposing the pressing member 60 in the first assembly step includes disposing the pressing member 60 with the through portion located between the end portion 50b of the both end portions and the plurality of switching elements in the second direction, and the fixing the switching module 40 to the heat sink 98 together with the circuit board 32 in the second assembly step at least includes fixing the switching module 40 to the heat sink 98 using a fixing member 88 disposed in the through portion.

### REFERENCE SIGNS LIST

1 Power conversion device, 2 Power conversion circuit, 14a, 15a Capacitor, 21U, 22U, 23U, 24U Switching element, 21W, 22W, 23W, 24W Switching element, 28 Main body portion, 29 Lead terminal, 32 Circuit board, 32a Front surface, 32b Back surface, 40 Switching module, 50 Case member, 50a, 50b End portion, 53, 56 Accommodation portion, 60 Pressing member, 62 Connection portion, 64 Pressing portion, 69 Through hole, 70 Cover member, 72 Top plate, 72a Upper surface, 76 Fixing portion, 80U, 80W Bus bar, 88 Fixing member, 98 Heat sink.

1. A switching module for use in a power conversion circuit, comprising:
a case member formed to extend in a first direction and a second direction orthogonal to each other;
one or more switching elements disposed to face the case member in a stacking direction orthogonal to the first direction and the second direction; and
a pressing member configured to press at least part of the one or more switching elements toward one side in the stacking direction via the case member, wherein
the one or more switching elements are disposed closer to one end portion of both end portions of the case member in the second direction.

2. The switching module according to claim 1, wherein the pressing member has a through portion formed to be located between another end portion of both end portions and the one or more switching elements in the second direction, and to fix the switching module.

3. The switching module according to claim 2, wherein
the one or more switching elements are a plurality of switching elements, and
the plurality of switching elements are disposed side by side along the first direction.

4. The switching module according to claim 3, wherein
the pressing member is formed to be configured to press two or more elements among the plurality of switching elements, and
the pressing member includes: a connection portion in which the through portion is formed; and two or more pressing portions configured to press the two or more elements, respectively, and connected to the connection portion in a state of being separated from each other in the first direction.

5. The switching module according to claim 1, wherein
the case member includes a first accommodation portion and a second accommodation portion having opening portions facing opposite to each other in the stacking direction,
the pressing member is provided in the first accommodation portion, and
the one or more switching elements are provided in the second accommodation portion.

6. The switching module according to claim 1, wherein
a switching element included in the one or more switching elements includes a main body portion and a plurality of lead terminals,
at least part of each of the plurality of lead terminals is formed through the case member, and extends in a direction intersecting the first direction and the second direction, and
the plurality of lead terminals are disposed on a line extending in the first direction.

7. The switching module according to claim 6, wherein the one end portion, the plurality of lead terminals, and the main body portion are disposed in this order in the second direction.

8. The switching module according to claim 1, further comprising a cover member attached to the case member so as to cover the pressing member.

9. The switching module according to claim 8, wherein the cover member includes: a top plate configured to cover the pressing member; and a fixing portion that is provided on an upper surface of the top plate opposite to a surface facing the pressing member, and is fittable into a hole formed in a member to which the switching module is attached.

10. The switching module according to claim 1, wherein
the one or more switching elements are a plurality of switching elements,
the power conversion circuit is a conversion circuit that outputs a three-phase alternating current, and
the plurality of switching elements are capable of forming one arm of the power conversion circuit related to one phase of the three-phase alternating current.

11. The switching module according to claim 1, wherein
the one or more switching elements are a plurality of switching elements, and
the plurality of switching elements are elements disposed at mutually corresponding portions of the arm of the power conversion circuit.

12. A power conversion device comprising:
the switching module according to claim 1;
a heat sink to which the switching module is fixed; and
a circuit board to which one or more lead terminals included in the one or more switching element are electrically connected, wherein
the switching module is fixed to the heat sink together with the circuit board, with at least part of the one or more switching elements pressed toward the heat sink by the pressing member.

13. The power conversion device according to claim 12, wherein
the circuit board includes a first principal surface and a second main surface facing opposite to each other,
the power conversion device further includes a capacitor provided on the first principal surface,
the switching module is provided to face the second main surface, and
at least part of the capacitor is disposed to overlap the switching module, as viewed in a direction orthogonal to the first principal surface.

14. The power conversion device according to claim 12, wherein
the circuit board includes a first principal surface and a second main surface facing opposite to each other,
the power conversion device further includes a bus bar electrically connected to a lead terminal for a main circuit of the power conversion circuit included in the one or more switching elements, and
the bus bar is provided on the first principal surface while intersecting the first principal surface.

15. The power conversion device according to claim 12, wherein
the circuit board is partitioned into a high-voltage region and a low-voltage region, with a virtual line extending along the first direction in a vicinity of the one or more lead terminals included in the one or more switching elements serving as a boundary,
the high-voltage region is a region where a main circuit of the power conversion circuit is formed, and
the low-voltage region is a region where a component operating at a lower voltage than the main circuit is disposed.

16. The power conversion device according to claim 15, wherein
the circuit board includes a first principal surface and a second main surface facing opposite to each other,
the power conversion device further includes a bus bar electrically connected to the lead terminal for the main circuit included in the one or more switching elements, and
the bus bar is located on the virtual line and is provided on the first principal surface while intersecting the first principal surface.

17. A manufacturing method for a power conversion device, the method comprising:
a first assembling step of assembling a switching module;
an attachment step of attaching the switching module to a circuit board;
a board step of performing soldering on the circuit board after the attachment step; and
a second assembly step of fixing the switching module attached to the circuit board to a heat sink after the board step, wherein
the first assembly step includes:
preparing one or more switching elements, a case member formed to extend in a first direction and a second direction orthogonal to each other, and a pressing member configured to press at least part of the one or more switching elements;
disposing the one or more switching elements to be positioned closer to one end portion of both end portions of the case member in the second direction and to face the case member in a stacking direction orthogonal to the first direction and the second direction; and
disposing the pressing member to overlap at least part of the one or more switching elements via the case member in the stacking direction, and
the second assembly step includes fixing the switching module to the heat sink together with the circuit board such that at least part of the one or more switching elements is pressed toward the heat sink by the pressing member.

18. The manufacturing method according to claim 17, wherein
the one or more switching elements are a plurality of switching elements,
the pressing member has a through portion formed to fix the switching module,
the disposing the one or more switching elements in the first assembly step includes disposing the plurality of switching elements side by side along the first direction,
the disposing the pressing member in the first assembly step includes disposing the pressing member with the through portion located between another end portion of both end portions and the plurality of switching elements in the second direction, and
the fixing the switching module to the heat sink together with the circuit board in the second assembly step at least includes fixing the switching module to the heat sink using a fixing member disposed in the through portion.
